(19) United States
(12) Patent Application Publication
(10) Pub. No.: US 2023/0178572 A1
(43) Pub. Date: Jun. 8, 2023

(54) ELECTRONIC DEVICE

(71) Applicant: InnoLux Corporation, Miao-Li County (TW)

(72) Inventors: Te-Yu LEE, Miao-Li County (TW); Yu-Tsung LIU, Miao-Li County (TW); Wei-Ju LIAO, Miao-Li County (TW)

(21) Appl. No.: 18/052,906

(22) Filed: Nov. 4, 2022

(30) Foreign Application Priority Data
Dec. 3, 2021 (CN) 202111465957.X
Jul. 29, 2022 (CN) 202210903336.3

(51) Int. Cl. H01L 27/146; G02B 1/115; G02B 1/118; G02B 1/02; G02B 1/111; G06V 40/13

(52) U.S. Cl. CPC H01L 27/1462; G02B 1/115; G02B 1/118; G02B 1/02; G02B 1/111; H01L 27/14678; G06V 40/1318

(57) ABSTRACT

An electronic device is provided. The electronic device includes a sensing device. The sensing device includes an anti-reflection unit, a circuit layer and a light-sensing element. The circuit layer includes a thin-film transistor and is disposed on the anti-reflection unit. The light-sensing element is disposed on the circuit layer and is electrically connected to the thin-film transistor.

### CROSS REFERENCE TO RELATED APPLICATIONS

This application claims priority of China Patent Application No. 202111465957.X, filed on Dec. 3, 2021, and China Patent Application No. 202210903336.3, filed on Jul. 29, 2022, the entirety of which are incorporated by reference herein.

### BACKGROUND

### Technical Field

The present disclosure relates to an electronic device, and in particular it relates to an electronic device with an anti-reflection unit.

### Description of the Related Art

Fingerprint sensing technology is suitable for personal identification or authentication and is widely used in modern daily life. Optical fingerprint recognition is one of the technologies that has attracted a lot of attention and is largely trusted, and has excellent potential for application in various electronic devices.

In general, an effective optical fingerprint sensor must have a high degree of security (i.e. low false acceptance rate (FAR); the biometric system must have a low probability of misidentifying illegal users as legitimate users), and must be convenient to use (i.e. low false rejection rate (FRR); the biometric system must have a low probability of misjudging legitimate users as illegal users). In order to reduce the probability of misjudgment by the optical fingerprint sensor, it is necessary to exclude any source that may interfere with the light signal used to identify the fingerprint.

### SUMMARY

In accordance with one embodiment of the present disclosure, an electronic device is provided. The electronic device includes a sensing device. The sensing device includes an anti-reflection unit, a circuit layer and a light-sensing element. The circuit layer includes a thin-film transistor and is disposed on the anti-reflection unit. The light-sensing element is disposed on the circuit layer and is electrically connected to the thin-film transistor.

In accordance with one embodiment of the present disclosure, an electronic device is provided. The electronic device includes a sensing device. The sensing device includes a circuit layer, a light-sensing element and an anti-reflection unit. The circuit layer includes a thin-film transistor. The light-sensing element is disposed on the circuit layer and electrically connected to the thin-film transistor. The anti-reflection unit is disposed on the circuit layer to absorb light passing through the light-sensing element.

In accordance with one embodiment of the present disclosure, an electronic device is provided. The electronic device includes a sensing device. The sensing device includes a substrate, an anti-reflection layer, a circuit layer and a light-sensing element. The substrate includes a first side and a second side opposite the first side. The anti-reflection layer is disposed on the first side. The circuit layer includes a thin-film transistor and is disposed on the second side. The light-sensing element is disposed on the circuit layer and is electrically connected to the thin-film transistor.

A detailed description is given in the following embodiments with reference to the accompanying drawings.

### BRIEF DESCRIPTION OF THE DRAWINGS

The disclosure can be more fully understood from the following detailed description when read with the accompanying figures. It is worth noting that in accordance with standard practice in the industry, various features are not drawn to scale. In fact, the dimensions of the various features may be arbitrarily increased or reduced for clarity of discussion.

FIG. 1 shows a cross-sectional view of an electronic device in accordance with one embodiment of the present disclosure;

FIG. 2 shows a cross-sectional view of an electronic device in accordance with one embodiment of the present disclosure;

FIG. 3 shows a cross-sectional view of an electronic device in accordance with one embodiment of the present disclosure;

FIG. 4 shows a cross-sectional view of an electronic device in accordance with one embodiment of the present disclosure;

FIG. 5 shows a cross-sectional view of an electronic device in accordance with one embodiment of the present disclosure;

FIG. 6 shows a cross-sectional view of an electronic device in accordance with one embodiment of the present disclosure;

FIG. 7 shows a cross-sectional view of an electronic device in accordance with one embodiment of the present disclosure;

FIG. 8A shows a cross-sectional view of an electronic device in accordance with one embodiment of the present disclosure;

FIG. 8B shows a cross-sectional view of an electronic device in accordance with one embodiment of the present disclosure;

FIG. 8C shows a cross-sectional view of an electronic device in accordance with one embodiment of the present disclosure.

### DETAILED DESCRIPTION

Various embodiments or examples are provided in the following description to implement different features of the present disclosure. The elements and arrangement described in the following specific examples are merely provided for introducing the present disclosure and serve as examples without limiting the scope of the present disclosure. For example, when a first component is referred to as “on a second component”, it may directly contact the second component, or there may be other components in between, and the first component and the second component do not come in direct contact with one another.

It should be understood that additional operations may be provided before, during, and/or after the described method. In accordance with some embodiments, some of the stages (or steps) described below may be replaced or omitted.

In this specification, spatial terms may be used, such as “below”, “lower”, “above”, “higher” and similar terms, for briefly describing the relationship between an element relative to another element in the figures. Besides the directions illustrated in the figures, the devices may be used or operated in different directions. When the device is turned to different directions (such as rotated 45 degrees or other directions), the spatially related adjectives used in it will also be interpreted according to the turned position. In addition, in this specification, expressions such as “first material layer disposed above/on/over a second material layer”, may indicate the direct contact of the first material layer and the second material layer, or it may indicate a non-contact state with one or more intermediate layers between the first material layer and the second material layer. In the above situation, the first material layer may not be in direct contact with the second material layer. In some embodiments of the present disclosure, terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Herein, the terms “about”, “around” and “substantially” typically mean a value is in a range of +/−15% of a stated value, typically a range of +/−10% of the stated value, typically a range of +/−5% of the stated value, typically a range of +/−3% of the stated value, typically a range of +/−2% of the stated value, typically a range of +/−1% of the stated value, or typically a range of +/−0.5% of the stated value. The stated value of the present disclosure is an approximate value. Namely, the meaning of “about”, “around” and “substantially” still exists even if there is no specific description of “about”, “around” and “substantially”.

It should be understood that, although the terms “first”, “second”, “third”, etc. may be used herein to describe various elements, components, regions, layers, portions and/or sections, these elements, components, regions, layers, portions and/or sections should not be limited by these terms. These terms are only used to distinguish one element, component, region, layer, portion or section from another element, component, region, layer, portion or section. Thus, a first element, component, region, layer, portion or section discussed below could be termed a second element, component, region, layer, portion or section without departing from the teachings of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

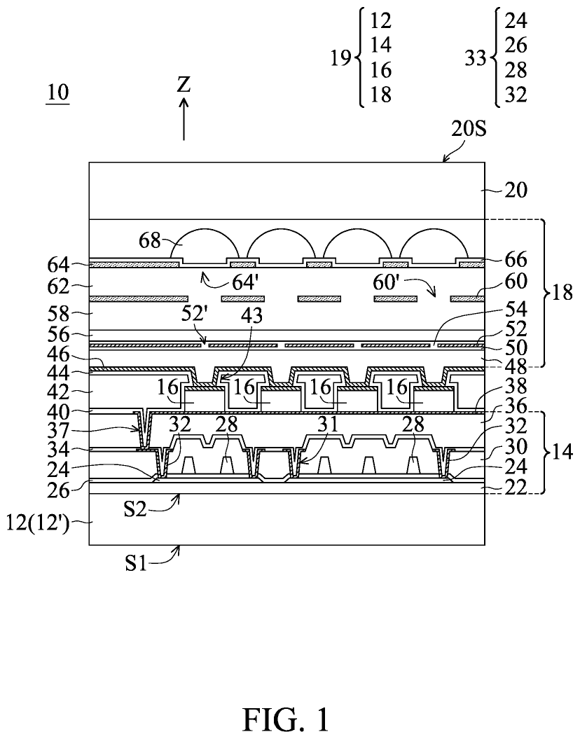

Referring to FIG. 1, in accordance with one embodiment of the present disclosure, an electronic device 10 is provided. FIG. 1 is a cross-sectional view of the electronic device 10. As shown in FIG. 1, the electronic device 10 includes a sensing device 19. The sensing device 19 may include an anti-reflection unit 12, a circuit layer 14 and a light-sensing element 16. The circuit layer 14 may be disposed on the anti-reflection unit 12. The light-sensing element 16 may be disposed on the circuit layer 14. The circuit layer 14 may include a thin-film transistor 33. The thin-film transistor 33 may include a first insulating layer 26, a first metal layer 28, a semiconductor layer 24 and a second metal layer 32. The first metal layer 28 may include a gate electrode. The second metal layer 32 may include a source electrode and a drain electrode. The first insulating layer 26 may be disposed between the first metal layer 28 and the second metal layer 32. The light-sensing element 16 may be electrically connected to the thin-film transistor 33. For example, the light-sensing element 16 may be electrically connected to an electrode formed by the second metal layer 32 (e.g., a drain electrode). The structure and material composition of the above elements are detailed as follows.

As shown in FIG. 1, the sensing device 19 may include a light-path guiding structure 18. The light-path guiding structure 18 may be disposed on the light-sensing element 16. The electronic device 10 may include the sensing device 19 and a display 20. The sensing device 19 may be disposed below the display 20. The sensing device 19 may be fixed under the display 20 by an adhesive layer (not shown). The display 20 may be disposed on the sensing device 19, for example, may be disposed on the light-path guiding structure 18.

In FIG. 1, the anti-reflection unit 12 may include a substrate 12′. The substrate 12′ includes a first side S1 and a second side S2 opposite the first side S1. The circuit layer 14 may be disposed on the second side S2 of the substrate 12′. In accordance with some embodiments, the anti-reflection unit 12 may be the substrate 12′, that is, the substrate 12′ itself may serve as an anti-reflection unit. The substrate 12′ may be a light-absorbing material. For example, the substrate 12′ may be composed of a material or structure that can absorb the light signal passing through the light-sensing element 16, or a material or structure that can absorb the light signal of a specific wavelength passing through the light-sensing element 16. In accordance with some embodiments, the anti-reflection unit 12 can prevent the light signal passing through the light-sensing element 16 from being reflected back to the light-sensing element 16 to affect the light-signal sensing effect of the light-sensing element 16. In accordance with some embodiments, the sensing device 19 may be used as a biometric sensing, for example, the sensing of fingerprint recognition. In some embodiments, the substrate 12′ may include a rigid substrate or a flexible substrate. In some embodiments, the rigid substrate may include a silicon substrate or a glass substrate, but the present disclosure is not limited thereto. In some embodiments, the flexible substrate may include a polyimide (PI) substrate, a polyethylene terephthalate (PET) substrate or a polycarbonate (PC) substrate, but the present disclosure is not limited thereto. In some embodiments, the thickness of the substrate 12′ may be between about 10 μm to about 100 μm, but the present disclosure is not limited thereto.

In FIG. 1, the circuit layer 14 may include a buffer layer 22, a semiconductor layer 24, a first insulating layer 26, a first metal layer 28, an interlayer dielectric (ILD) layer 30, a second metal layer 32, a second insulating layer 34, a first planarization layer 36 and a third metal layer 38. The buffer layer 22 is disposed on the substrate 12. The semiconductor layer 24 is disposed on the buffer layer 22. The first insulating layer 26 is disposed on the buffer layer 22 and covers the semiconductor layer 24. The first metal layer 28 is disposed on the first insulating layer 26. The interlayer dielectric (ILD) layer 30 is disposed on the first insulating layer 26 and covers the first metal layer 28, and an opening 31 is formed to expose a part of the semiconductor layer 24. The second metal layer 32 is disposed on the interlayer dielectric (ILD) layer 30 and fills the opening 31 to electrically connect to the semiconductor layer 24. Here, the first insulating layer 26 may serve as a gate insulating layer. The first metal layer 28 may include a gate electrode. The semiconductor layer 24 may serve as an active layer. The second metal layer 32 may include a source electrode and a drain electrode. Therefore, the first insulating layer 26, the first metal layer 28, the semiconductor layer 24 and the second metal layer 32 can constitute the thin-film transistor 33. The second insulating layer 34 is disposed on the interlayer dielectric (ILD) layer 30 and covers the second metal layer 32. The first planarization layer 36 is disposed on the second insulating layer 34, and an opening 37 is formed to expose a part of the second metal layer 32. The third metal layer 38 is disposed on the first planarization layer 36 and fills the opening 37 to electrically connect to the second metal layer 32.

In some embodiments, the buffer layer 22, the first insulating layer 26, the interlayer dielectric (ILD) layer 30, the second insulating layer 34 and the first planarization layer 36 may include organic materials or inorganic materials, for example, silicon oxide, silicon nitride, silicon oxynitride or a combination thereof, but the present disclosure is not limited thereto. In some embodiments, the semiconductor layer 24 may include amorphous silicon, polysilicon or metal oxides, but the present disclosure is not limited thereto. In some embodiments, the first metal layer 28, the second metal layer 32 and the third metal layer 38 may include molybdenum, aluminum, copper, titanium or a combination thereof, such as molybdenum/aluminum/molybdenum, titanium/aluminum/titanium or titanium/aluminum/molybdenum, but the present disclosure is not limited thereto. Other suitable conductive materials are also applicable to the present disclosure.

In FIG. 1, the light-sensing element 16 may be disposed on the circuit layer 14 and electrically connected to the thin-film transistor 33. For example, the light-sensing element 16 may be electrically connected to an electrode (e.g., a drain electrode) formed by the second metal layer 32. The third metal layer 38 may be disposed on the second metal layer 32 and disposed in the opening 37 of the first planarization layer 36 to electrically connect to the drain electrode formed by the second metal layer 32. Specifically, the light-sensing element 16 may be disposed on the third metal layer 38 and electrically connected to the third metal layer 38. Therefore, the light-sensing element 16 may be electrically connected to the thin-film transistor 33 through the third metal layer 38. The light-sensing element 16 may include elements that are responsive to light. In some embodiments, the light-sensing element 16 may include a photodiode, but the present disclosure is not limited thereto. The photodiode may include an organic photodiode or an inorganic light-emitting diode, but the present disclosure is not limited thereto. The photodiode may be PN type or PIN type, but the present disclosure is not limited thereto. A third insulating layer 40 is disposed on the first planarization layer 36 and covers the third metal layer 38 and a part of the light-sensing element 16. A second planarization layer 42 is disposed on the third insulating layer 40, and an opening 43 is formed to expose a part of the light-sensing element 16. A fourth insulating layer 44 is disposed on the second planarization layer 42 and fills the opening 43, exposing a part of the light-sensing element 16. An electrode layer 46 is disposed on the fourth insulating layer 44 and fills the opening 43 to electrically connect to the light-sensing element 16.

In some embodiments, the third insulating layer 40, the second planarization layer 42 and the fourth insulating layer 44 may include organic materials, inorganic materials or a combination thereof, for example, may include silicon oxide, silicon nitride, silicon oxynitride or a combination thereof, but the present disclosure is not limited thereto. In some embodiments, the electrode layer 46 may include indium tin oxide (ITO), but the present disclosure is not limited thereto. Other suitable conductive materials are also suitable for the present disclosure.

In FIG. 1, the light-path guiding structure 18 includes a third planarization layer 48, a fifth insulating layer 50, a fourth metal layer 52, a sixth insulating layer 54, a fourth planarization layer 56, a first dielectric layer 58, a first light-shielding layer 60, a second dielectric layer 62, a second light-shielding layer 64, a seventh insulating layer 66 and microlenses 68. The third planarization layer 48 is disposed on the electrode layer 46. The fifth insulating layer 50 is disposed on the third planarization layer 48. The fourth metal layer 52 is disposed on the fifth insulating layer 50. The fourth metal layer 52 has a plurality of openings 52′. The sixth insulating layer 54 is disposed on the fourth metal layer 52 and fills the opening 52′ of the fourth metal layer 52. The fourth planarization layer 56 is disposed on the sixth insulating layer 54. The first dielectric layer 58 is disposed on the fourth planarization layer 56. The first light-shielding layer 60 is disposed on the first dielectric layer 58. The first light-shielding layer 60 includes a plurality of first openings 60′. The second dielectric layer 62 is disposed on the first light-shielding layer 60 and fills the first opening 60′ of the first light-shielding layer 60. The second light-shielding layer 64 is disposed on the second dielectric layer 62. The second light-shielding layer 64 includes a plurality of second openings 64′. The seventh insulating layer 66 is disposed on the second light-shielding layer 64 and fills the second opening 64′ of the second light-shielding layer 64. The microlenses 68 may be disposed on the seventh insulating layer 66 and may correspond to the light-sensing element 16 below.

In accordance with some embodiments, as shown in FIG. 1, a finger can touch the surface 20S of the display 20. The light generated by the display 20 can be reflected by the finger to generate reflected light. The reflected light can reach the light-sensing element 16 through the microlenses 68, the second openings 64′ of the second light-shielding layer 64 and the first openings 60′ of the first light-shielding layer 60. The anti-reflection unit 12 located under the light-sensing element 16 can absorb the light signal passing through the light-sensing element 16 to prevent the light signal passing through the light-sensing element 16 from being reflected back to the light-sensing element 16 to affect the sensing quality of the light-sensing element 16. In accordance with some embodiments, the anti-reflection unit 12 can prevent the light signal passing through the light-sensing element 16 from being reflected back to the light-sensing element 16 to affect the light-signal sensing effect of the light-sensing element 16. In accordance with some embodiments, the sensing device 19 may be used as a biometric sensing, for example, the sensing of fingerprint recognition.

In accordance with some embodiments, the arrangement of the light-path guiding structure 18 can guide the path of the light, but it is not an essential element. For example, the first opening 60′ of the first light-shielding layer 60 can prevent light leakage from a large angle. The second openings 64′ of the second light-shielding layer 64 can prevent light leakage from the microlenses 68. In accordance with some embodiments, the fourth metal layer 52 may have openings 52′. In accordance with some embodiments, the opening 43 of the second planarization layer 42, the first opening 60′ of the first light-shielding layer 60, the second opening 64′ of the second light-shielding layer 64 and the opening 52′ of the fourth metal layer 52 may overlap the light-sensing element 16 in the normal direction (e.g., Z direction in FIG. 1) of the substrate 12′. In this way, light can be transmitted to the light-sensing element 16 through the second opening 64′, the first opening 60′, the opening 52′ and the opening 43. In accordance with some embodiments, the microlens 68 with a light-collecting effect may overlap the light-sensing element 16 in the normal direction (Z direction) of the substrate 12′, which can condense the light onto the light-sensing element 16.

In accordance with some embodiments, the sizes of the second opening 64′, the first opening 60′ and the opening 52′ may not be limited. The width of the second opening 64′ may be greater than, less than or equal to the width of the first opening 60′. The width of the first opening 60′ may be greater than, less than or equal to the width of the opening 52′. In accordance with some embodiments, the width of the second opening 64′ may be greater than the width of the first opening 60′, and the width of the first opening 60′ may be greater than the width of the opening 52′, but not limited thereto. The width of the above-mentioned second opening 64′, first opening 60′, opening 52′ and opening 43 may be measured in the same cross-sectional view.

In some embodiments, the third planarization layer 48, the fifth insulating layer 50, the sixth insulating layer 54, the fourth planarization layer 56, the first dielectric layer 58, the second dielectric layer 62 and the seventh insulating layer 66 may include organic materials or inorganic materials, for example, silicon oxide, silicon nitride, silicon oxynitride or a combination thereof, but the present disclosure is not limited thereto. In some embodiments, the fourth metal layer 52 may include molybdenum, aluminum, copper, titanium or a combination thereof, such as molybdenum/aluminum/molybdenum, titanium/aluminum/titanium or titanium/aluminum/molybdenum, but the present disclosure is not limited thereto. Other suitable conductive materials are also applicable to the present disclosure. In some embodiments, the first light-shielding layer 60 and the second light-shielding layer 64 may include chromium, chromium oxide or black resin, but the present disclosure is not limited thereto.

In some embodiments, the display 20 may include a backlight module (not shown) and a display panel (not shown), but the present disclosure is not limited thereto. In some embodiments, the backlight module may include a light-source module, a reflective sheet, a light-guide plate, an optical film set and a back plate, but the present disclosure is not limited thereto. In some embodiments, the light-source module may include light-emitting diodes (LEDs), but the present disclosure is not limited thereto. In accordance with some embodiments, the display 20 may be a device with a display function. For example, the display 20 may be a liquid-crystal display, an organic light-emitting diode (OLED) display, an inorganic light-emitting diode display, a sub-millimeter light-emitting diode (mini LED) display, a micro light-emitting diode (micro LED) display or quantum-dot light-emitting diode (QLED/QDLED) display, but the present disclosure is not limited thereto. In some embodiments, the optical film set may include a lower diffuser film, an upper diffuser film, a lower brightening film, an upper brightening film or a prism sheet, but the present disclosure is not limited thereto. In some embodiments, the display 20 may include a lower polarizing film, a thin-film transistor layer, a color filter layer, an upper polarizing film and a glass cover, but the present disclosure is not limited thereto.

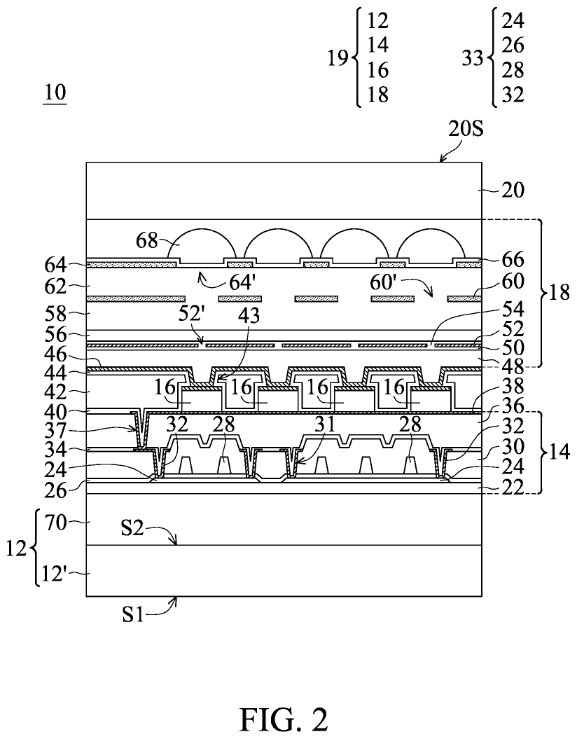

Referring to FIG. 2, in accordance with one embodiment of the present disclosure, an electronic device 10 is provided. FIG. 2 is a cross-sectional view of the electronic device 10.

The structure and material composition of respective elements of the electronic device 10 shown in FIG. 2 that are similar to those of the electronic device 10 shown in FIG. 1 are not repeated here. The main difference from FIG. 1 is that, in FIG. 2, the anti-reflection unit 12 includes a substrate 12′ and an anti-reflection layer 70. For example, an anti-reflection layer 70 is additionally disposed between the substrate 12′ and the circuit layer 14. The anti-reflection layer 70 is disposed on one side of the substrate 12′. Specifically, the substrate 12′ includes a first side S1 and a second side S2 opposite the first side S1. The anti-reflection layer 70 may be disposed on the second side S2 of the substrate 12′. The anti-reflection layer 70 may be, for example, a light-absorbing layer. In accordance with some embodiments, the anti-reflection layer 70 may include a light-absorbing material, for example, the anti-reflection layer 70 may include a colloid and a light-absorbing material doped in the colloid.

The anti-reflection layer 70 can suppress light reflection, which can absorb light of a specific wavelength, for example, visible light or light in the IR band. This particular wavelength of light ranges from about 400 nm to about 750 nm. The anti-reflection layer 70 has an absorptivity greater than 50% for light having a wavelength between about 400 nm and about 750 nm.

In some embodiments, the anti-reflection layer 70 may include semiconductor materials, organic insulating materials or inorganic insulating materials, but the present disclosure is not limited thereto. In some embodiments, the semiconductor material may include amorphous silicon, but the present disclosure is not limited thereto. In some embodiments, the organic insulating material may include acrylic-based polymer, polyimide, polyester, epoxy resin, or a combination thereof, or other suitable organic insulating materials. In some embodiments, the inorganic insulating materials suitable for the anti-reflection layer 70 may include silicon oxide, silicon nitride, silicon oxynitride, aluminum oxide, or a combination thereof, or other suitable inorganic insulating materials. In some embodiments, when the anti-reflection layer 70 is made of a semiconductor material, the thickness of the anti-reflection layer 70 may be between about 1 nm and about 2 μm, for example, between about 10 nm and about 2 μm, or between about 1 nm and about 5 nm, but the present disclosure is not limited thereto. In some embodiments, when the anti-reflection layer 70 is made of an organic insulating material, the thickness of the anti-reflection layer 70 may be between about 1 μm and about 15 μm, but the present disclosure is not limited thereto. In some embodiments, when the anti-reflection layer 70 is made of an inorganic insulating material, the thickness of the anti-reflection layer 70 may be between about 1 nm and about 100 nm, but the present disclosure is not limited thereto. In some embodiments, when the anti-reflection layer 70 is an organic insulating material, the optical properties of the material itself or the addition of color resist can be used to absorb light of a specific wavelength. In addition, the organic insulating material itself can be qualitatively changed by the process (for example, a high-temperature process), so as to increase the absorption of light of a specific wavelength.

The purpose of disposing the anti-reflection layer 70 is to prevent the light signal passing through the light-sensing element 16 from being reflected by other structures (e.g., the substrate) below the light-sensing element 16, since the light signal that hits other structures (e.g., the substrate) and is reflected back to the light-sensing element 16 will interfere with the light-sensing element 16 to sense the light signal reflected by the fingerprint, thereby affecting the quality of the output image of the fingerprint.

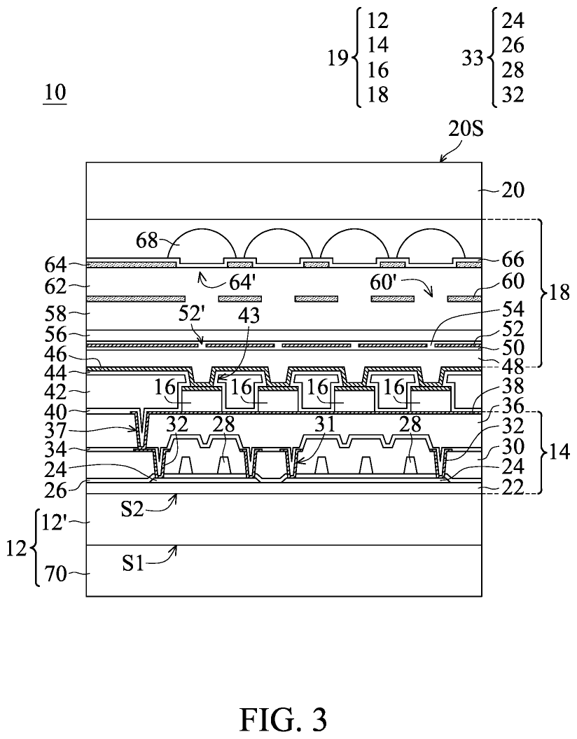

Referring to FIG. 3, in accordance with one embodiment of the present disclosure, an electronic device 10 is provided. FIG. 3 is a cross-sectional view of the electronic device 10.

The structure and material composition of respective element of the electronic device 10 shown in FIG. 3 that are similar to those of the electronic device 10 shown in FIG. 1 are not repeated here. The main difference from FIG. 1 is that, in FIG. 3, the anti-reflection unit 12 includes a substrate 12′ and an anti-reflection layer 70, and the anti-reflection layer 70 is disposed on one side of the substrate 12′. Specifically, the substrate 12′ includes a first side S1 and a second side S2 opposite the first side S1. The anti-reflection layer 70 may be disposed on the first side S1 of the substrate 12′. The circuit layer 14 may be disposed on the second side S2. The circuit layer 14 may include a thin-film transistors 33. The light-sensing element 16 is disposed on the circuit layer 14 and electrically connected to the thin-film transistor 33. The material composition and sizes of the anti-reflection layer 70 and other elements shown in FIG. 3 are as described above, and will not be repeated here. The anti-reflection layer 70 disposed under the substrate 12′ (on the first side S1) can be used for absorbing the light signal passing through the light-sensing element 16 and the substrate 12 to prevent the light signal from being reflected back to the light-sensing element 16.

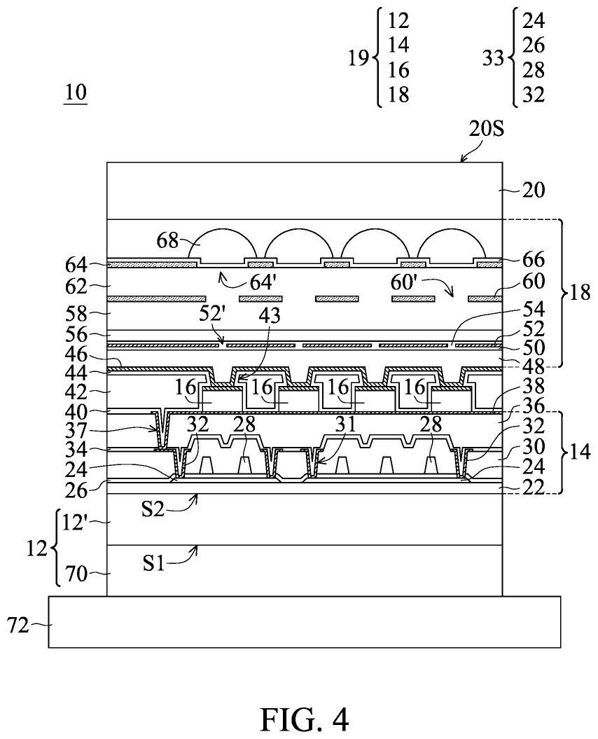

Referring to FIG. 4, in accordance with one embodiment of the present disclosure, an electronic device 10 is provided. FIG. 4 is a cross-sectional view of the electronic device 10.

The structure and material composition of respective element of the electronic device 10 shown in FIG. 4 that are similar to those of the electronic device 10 shown in FIG. 3 are not repeated here. The main difference from FIG. 3 is that, in FIG. 4, the electronic device 10 includes a frame 72, and the sensing device 19 is attached to the frame 72 through the anti-reflection layer 70. The anti-reflection layer 70 may be disposed on the first side S1 of the substrate 12′. The frame 72 may be disposed on the first side S1. The circuit layer 14 may be disposed on the second side S2.

In FIG. 4, the anti-reflection layer 70 may include a colloid with adhesive properties. In accordance with some embodiments, the anti-reflection layer 70 may be, for example, a light-absorbing layer. In accordance with some embodiments, the anti-reflection layer 70 may include a light-absorbing material, for example, the anti-reflection layer 70 may include a colloid and a light-absorbing material doped in the colloid. In this way, when the sensing device 19 is assembled into the electronic device 10, the anti-reflection layer 70 of the sensing device 19 can be directly attached to the frame 72 of the electronic device 10. For example, the anti-reflection layer 70 of the sensing device 19 can be directly attached to the middle frame of the mobile phone module, thereby shortening the process and saving costs. In some embodiments, the adhesive colloid may include acrylic-based colloid, polyurethane (PU)-based colloid or silicon-based colloid (silicone), but the present disclosure is not limited thereto. In some embodiments, the light-absorbing material may be a color resist, which can absorb light of a specific wavelength, for example, a black color resist or a green color resist.

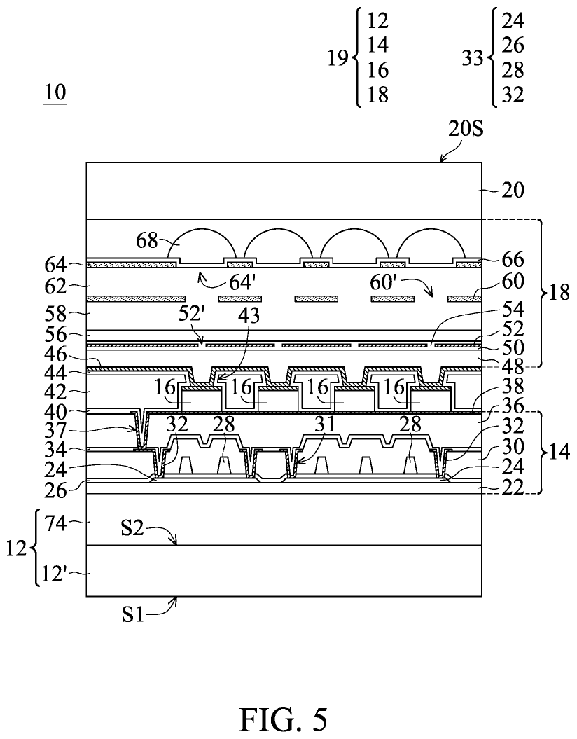

Referring to FIG. 5, in accordance with one embodiment of the present disclosure, an electronic device 10 is provided. FIG. 5 is a cross-sectional view of the electronic device 10.

The structure and material composition of respective element of the electronic device 10 shown in FIG. 5 that are similar to those of the electronic device 10 shown in FIG. 1 are not repeated here. The main difference from FIG. 1 is that, in FIG. 5, the anti-reflection unit 12 includes a substrate 12′ and an anti-reflection layer 74. That is, an anti-reflection layer 74 is additionally disposed between the substrate 12′ and the circuit layer 14. The anti-reflection layer 74 is disposed on one side of the substrate 12′. Specifically, the substrate 12′ includes a first side S1 and a second side S2 opposite the first side S1. The anti-reflection layer 74 may be disposed on the second side S2 of the substrate 12′.

In some embodiments, the anti-reflection layer 74 may be composed of metal material or an oxide film. In some embodiments, when the anti-reflection layer 74 is a metal material, the anti-reflection layer 74 may include copper (Cu), aluminum (Al), molybdenum (Mo), indium (In), ruthenium (Ru), tin (Sn), gold (Au), platinum (Pt), zinc (Zn), silver (Ag), titanium (Ti), lead (Pb), nickel (Ni), chromium (Cr), magnesium (Mg), palladium (Pd), or an alloy of the above materials, or a combination of the above materials, or other suitable metal materials.

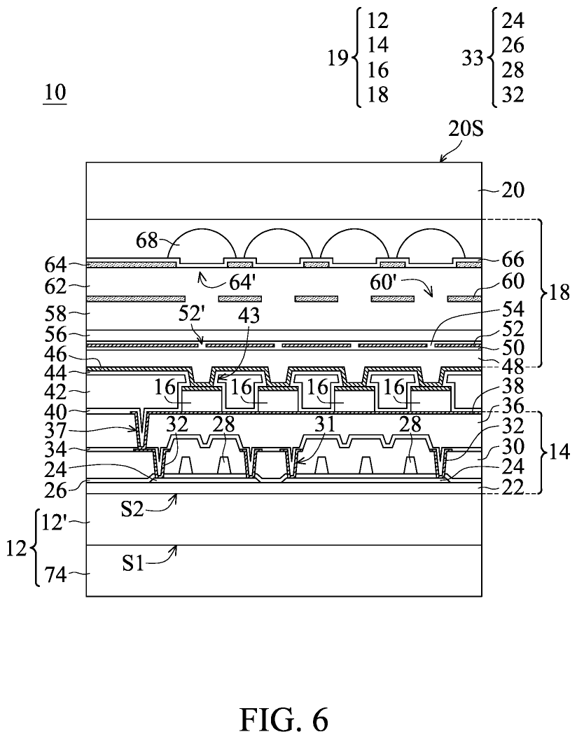

Referring to FIG. 6, in accordance with one embodiment of the present disclosure, an electronic device 10 is provided. FIG. 6 is a cross-sectional view of the electronic device 10.

The structure and material composition of respective element of the electronic device 10 shown in FIG. 6 that are similar to those of the electronic device 10 shown in FIG. 1 are not repeated here. The main difference from FIG. 1 is that, in FIG. 6, the anti-reflection unit 12 includes a substrate 12′ and an anti-reflection layer 74, and the anti-reflection layer 74 is disposed on one side of the substrate 12′. Specifically, the anti-reflection layer 74 may be disposed on the first side S1 of the substrate 12′. The circuit layer 14 may be disposed on the second side S2. The material composition of the anti-reflection layer 74 shown in FIG. 6 is similar to that of the anti-reflection layer 74 shown in FIG. 5, and details are not repeated here.

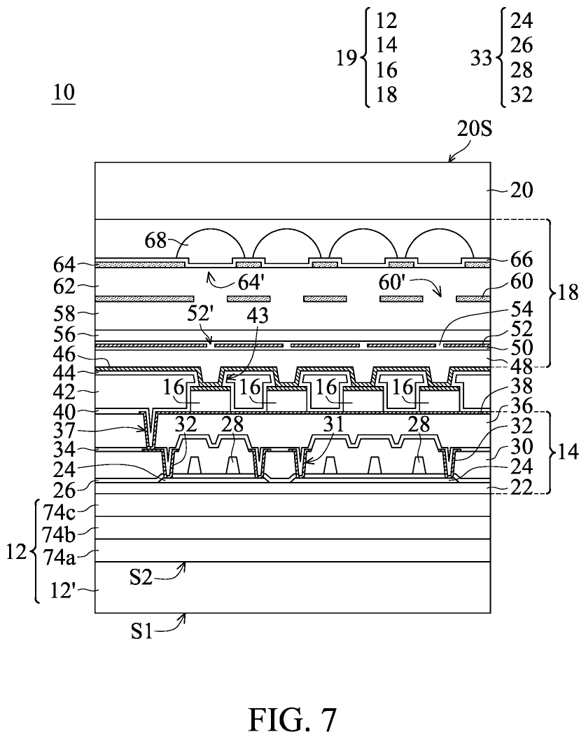

Referring to FIG. 7, in accordance with one embodiment of the present disclosure, an electronic device 10 is provided. FIG. 7 is a cross-sectional view of the electronic device 10.

The structure and material composition of respective element of the electronic device 10 shown in FIG. 7 that are similar to those of the electronic device 10 shown in FIG. 1 are not repeated here. The main difference from FIG. 1 is that, in FIG. 7, the anti-reflection unit 12 may include a substrate 12′ and an anti-reflection layer 74. The anti-reflection layer 74 may include multiple layers (74a, 74b and 74c). That is, a multi-layered anti-reflection layer may be additionally disposed between the substrate 12′ and the circuit layer 14. The anti-reflection layer 74 includes a first anti-reflection layer 74a, a second anti-reflection layer 74b and a third anti-reflection layer 74c, but the present disclosure is not limited thereto. The anti-reflection layer with other numbers of layers are also suitable for the present disclosure, for example, two or four layers (inclusive) or more. In FIG. 7, the first anti-reflection layer 74a is disposed on the substrate 12′. The second anti-reflection layer 74b is disposed on the first anti-reflection layer 74a. The third anti-reflection layer 74c is disposed on the second anti-reflection layer 74b. The anti-reflection layer 74 is disposed on one side of the substrate 12′. Specifically, the substrate 12′ includes a first side S1 and a second side S2 opposite the first side S1. The anti-reflection layer 74 may be disposed on the second side S2 of the substrate 12′.

In some embodiments, the first anti-reflection layer 74a is made of an insulating material, the second anti-reflection layer 74b is made of a metal material, and the third anti-reflection layer 74c is made of an insulating material, but the present disclosure is not limited thereto, and other material combinations are also applicable to the present disclosure. In accordance with some embodiments, the anti-reflection layer 74 may include a first inorganic layer 74a, a metal layer 74b and a second inorganic layer 74c. The metal layer 74b is disposed on the first inorganic layer 74b. The second inorganic layer 74c is disposed on the metal layer 74b, but the present disclosure is not limited thereto.

In some embodiments, the insulating material used in the anti-reflection layer may include inorganic insulating materials or organic insulating materials. In some embodiments, the inorganic insulating material may include silicon oxide, silicon nitride, silicon oxynitride, aluminum oxide, or a combination thereof, or other suitable inorganic insulating materials. In some embodiments, the organic insulating material may include perfluoroalkoxy alkane (PFA), polytetrafluoroethylene (PTFE), fluorinated ethylene propylene (FEP), polyethylene, or a combination thereof, or other suitable organic insulating materials. In some embodiments, the metal materials used in the anti-reflection layer may include may include copper (Cu), aluminum (Al), molybdenum (Mo), indium (In), ruthenium (Ru), tin (Sn), gold (Au), platinum (Pt), zinc (Zn), silver (Ag), titanium (Ti), lead (Pb), nickel (Ni), chromium (Cr), magnesium (Mg), palladium (Pd), or an alloy of the above materials, or a combination of the above materials, or other suitable metal materials. In some embodiments, when the anti-reflection layer is an insulating material, the thickness thereof ranges from about 500 angstroms to about 1,000 angstroms. In some embodiments, when the anti-reflection layer is made of a metal material, the thickness thereof ranges from about 40 angstroms to about 200 angstroms, or from about 40 angstroms to about 160 angstroms.

In the present disclosure, the multi-layered anti-reflection layer causes the reflected light generated when the light signal passing through the light sensing element 16 passes through the different films of the anti-reflection layer to destructively interfere with each other, offsets the light intensity, and achieves the effect of anti-reflection.

In some embodiments, the surface of the anti-reflection layer 12 may include a plurality of microstructures (not shown). The anti-reflection layer 12 may have an uneven surface. For example, the surface of the anti-reflection layer 12 has an undulating structure. For example, the surface of the anti-reflection layer 12 has a curved configuration. In this way, the microstructures on the surface of the anti-reflection layer 12 can disperse the light, so that the light signal passing through the light-sensing element 16 can be diffused after hitting the anti-reflection layer, thereby reducing the light signal reflected back to the light-sensing element 16. The surface of the anti-reflection layer 12 may be closer to the surface of the display 20.

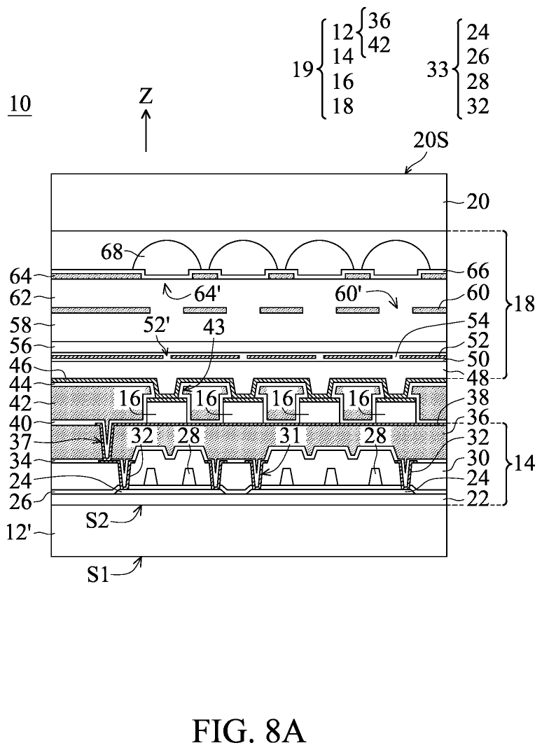

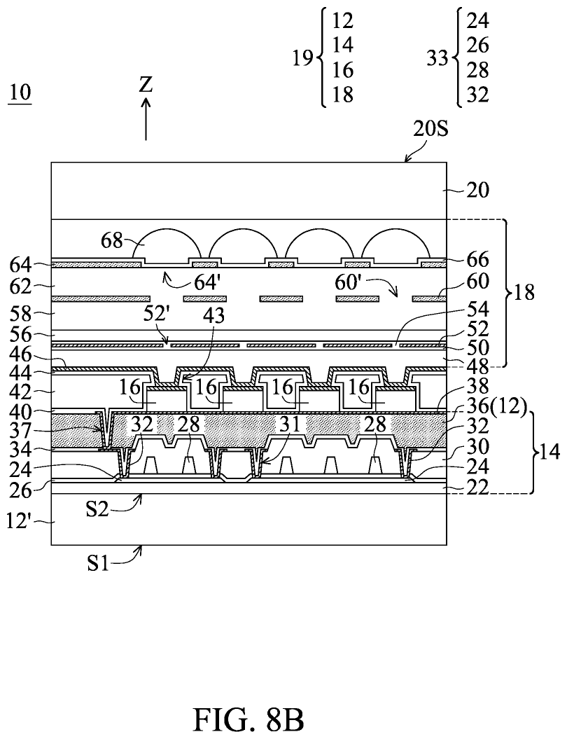

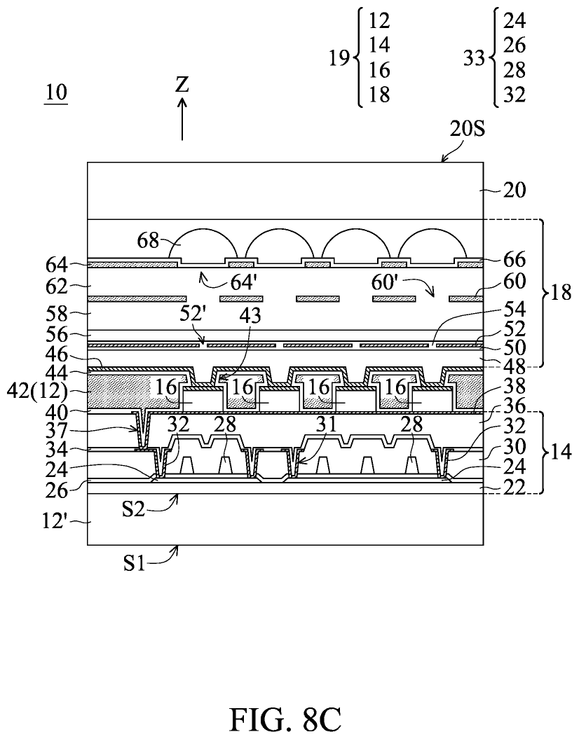

Referring to FIG. 8A, in accordance with one embodiment of the present disclosure, an electronic device 10 is provided. FIG. 8A is a cross-sectional view of the electronic device 10.

The structure and material composition of respective element of the electronic device 10 shown in FIG. 8A that are similar to those of the electronic device 10 shown in FIG. 1 are not repeated here. The main difference from FIG. 1 is that, in FIG. 8A, the anti-reflection unit 12 includes a first planarization layer 36 and a second planarization layer 42 disposed on the thin-film transistor 33. The first planarization layer 36 and the second planarization layer 42 are replaced by light-absorbing materials. The first planarization layer 36 and the second planarization layer 42 may be, for example, light-absorbing layers. In accordance with some embodiments, the first planarization layer 36 and the second planarization layer 42 may include organic materials or inorganic materials added with black substances (e.g., carbon black or organic pigments), such as black photoresist or black resin, but the present disclosure is not limited thereto.

The first planarization layer 36 and the second planarization layer 42 can suppress light reflection, which can absorb light of a specific wavelength, for example, visible light or light in the IR band. This particular wavelength of light ranges from about 400 nm to about 750 nm. The first planarization layer 36 and the second planarization layer 42 have an absorptivity greater than 50% for light having a wavelength between about 400 nm and about 750 nm.

The first planarization layer 36 under the light-sensing element 16 and the second planarization layer 42 surrounding the light-sensing element 16 are replaced by black photoresist or black resin for the purpose of absorbing the light signal passing through the light-sensing element 16, to prevent the light signal passing through the light-sensing element 16 from being reflected back to the light-sensing element 16 by other structures below the light-sensing element 16. The light signal reflected back to the light-sensing element 16 from other structures will be received by the light-sensing element 16 together with the light signal reflected back to the light-sensing element 16 from the fingerprint, thereby affecting the output quality of the fingerprint image. In addition, the second planarization layer 42 surrounding the light-sensing element 16 can also absorb stray light from all directions towards the light-sensing element 16 to improve the output quality of the fingerprint image.

Referring to FIG. 8B, in accordance with one embodiment of the present disclosure, an electronic device 10 is provided. FIG. 8B is a cross-sectional view of the electronic device 10.

The structure and material composition of respective element of the electronic device 10 shown in FIG. 8B that are similar to those of the electronic device 10 shown in FIG. 1 are not repeated here. The main difference from FIG. 1 is that, in FIG. 8B, the anti-reflection unit 12 includes a first planarization layer 36 disposed on the thin-film transistor 33 and located below the light-sensing element 16. The first planarization layer 36 is replaced by light-absorbing materials. The first planarization layer 36 may be, for example, a light-absorbing layer. In accordance with some embodiments, the first planarization layer 36 may include organic materials or inorganic materials added with black substances (e.g., carbon black or organic pigments), such as black photoresist or black resin, but the present disclosure is not limited thereto.

Referring to FIG. 8C, in accordance with one embodiment of the present disclosure, an electronic device 10 is provided. FIG. 8C is a cross-sectional view of the electronic device 10.

The structure and material composition of respective element of the electronic device 10 shown in FIG. 8C that are similar to those of the electronic device 10 shown in FIG. 1 are not repeated here. The main difference from FIG. 1 is that, in FIG. 8C, the anti-reflection unit 12 includes a second planarization layer 42 disposed on the thin-film transistor 33 and surrounding the light-sensing element 16 to expose a part of the light-sensing element 16. The second planarization layer 42 is replaced by light-absorbing materials. The second planarization layer 42 may be, for example, a light-absorbing layer. In accordance with some embodiments, the second planarization layer 42 may include organic materials or inorganic materials added with black substances (e.g., carbon black or organic pigments), such as black photoresist or black resin, but the present disclosure is not limited thereto.

The electronic device of the present disclosure, as an optical fingerprint sensing device, is suitable for an electronic device with a display. The electronic device includes an optical fingerprint sensing array (e.g., the light-sensing element 16), a light-path guiding structure and a light-absorbing layer (or single-layered or multi-layered anti-reflection layer). The optical fingerprint sensing array is disposed below the display for realizing under-screen optical fingerprint sensing. The light-path guiding structure is disposed between the display and the optical fingerprint sensing array and transmits the light signal reflected by the fingerprint to the optical fingerprint sensing array. The light-absorbing layer is disposed under the optical fingerprint sensing array for absorbing the light signal passing through the optical fingerprint sensing array. The single-layered or multi-layered anti-reflection layer is used to avoid reflection of light signals passing through the optical fingerprint sensing array back to the optical fingerprint sensing array.

The electronic device of the present disclosure includes a sensing device, and the sensing device may include an anti-reflection unit. In accordance with some embodiments, the electronic device can avoid unnecessary reflected signals from interfering with the determination of sensing, thereby increasing safety and convenience.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods or steps. In addition, each claim constitutes an individual embodiment, and the claimed scope of the present disclosure includes the combinations of the claims and embodiments. The scope of protection of present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
a sensing device, comprising:
an anti-reflection unit;
a circuit layer comprising a thin-film transistor disposed on the anti-reflection unit; and
a light-sensing element disposed on the circuit layer and electrically connected to the thin-film transistor.

2. The electronic device as claimed in claim 1, wherein the anti-reflection unit comprises a substrate.

3. The electronic device as claimed in claim 1, wherein the anti-reflection unit comprises a substrate and an anti-reflection layer disposed on the substrate.

4. The electronic device as claimed in claim 3, wherein the anti-reflection layer comprises semiconductor materials.

5. The electronic device as claimed in claim 4, wherein the anti-reflection layer has a thickness ranging from 1 nm to 2 μm.

6. The electronic device as claimed in claim 3, wherein the anti-reflection layer comprises organic insulating materials.

7. The electronic device as claimed in claim 6, wherein the anti-reflection layer has a thickness ranging from 1 μm to 15 μm.

8. The electronic device as claimed in claim 3, wherein the anti-reflection layer comprises inorganic insulating materials.

9. The electronic device as claimed in claim 8, wherein the anti-reflection layer has a thickness ranging from 1 nm to 100 nm.

10. The electronic device as claimed in claim 3, wherein the anti-reflection layer comprises:
a first inorganic layer;
a metal layer disposed on the first inorganic layer; and
a second inorganic layer disposed on the metal layer.

11. The electronic device as claimed in claim 3, wherein the anti-reflection layer has a surface containing a plurality of microstructures.

12. An electronic device, comprising:
a sensing device, comprising:
a circuit layer comprising a thin-film transistor;
a light-sensing element disposed on the circuit layer and electrically connected to the thin-film transistor; and
an anti-reflection unit disposed on the circuit layer to absorb light passing through the light-sensing element.

13. The electronic device as claimed in claim 12, wherein the anti-reflection unit is disposed on the thin-film transistor.

14. The electronic device as claimed in claim 12, wherein the anti-reflection unit comprises a first planarization layer and a second planarization layer, the first planarization layer is located below the light-sensing element, the second planarization layer is disposed on the first planarization layer, and the second planarization layer surrounds the light-sensing element.

15. The electronic device as claimed in claim 14, wherein the first planarization layer and the second planarization layer comprise organic or inorganic materials with black substances added.

16. The electronic device as claimed in claim 12, wherein the anti-reflection unit comprises a planarization layer located below the light-sensing element, and the planarization layer comprises organic or inorganic materials with black substances added.

17. The electronic device as claimed in claim 12, wherein the anti-reflection unit comprises a planarization layer surrounding the light-sensing element, and the planarization layer comprises organic or inorganic materials with black substances added.

18. An electronic device, comprising:
a sensing device, comprising:
a substrate comprising a first side and a second side opposite the first side
an anti-reflection layer disposed on the first side;
a circuit layer comprising a thin-film transistor disposed on the second side; and
a light-sensing element disposed on the circuit layer and electrically connected to the thin-film transistor.

19. The electronic device as claimed in claim 18, further comprising a frame, wherein the sensing device is attached to the frame through the anti-reflection layer.

20. The electronic device as claimed in claim 18, wherein the anti-reflection layer comprises colloid and light-absorbing materials doped in the colloid.
